(19) United States
(12) Patent Application Publication
(10) Pub. No.: US 2020/0365410 A1
(43) Pub. Date: Nov. 19, 2020

(54) ETCHING DEVICE

(71) Applicant: TOYOTA JIDOSHA KABUSHIKI KAISHA, Toyota-shi (JP)

(72) Inventors: Daisuke SUGIZAKI, Nagakute-shi (JP); Kunio AKEDO, Nagakute-shi (JP); Koji NODA, Nagakute-shi (JP); Eiko ISHII, Nagakute-shi (JP); Kenji NAKASHIMA, Nagakute-shi (JP)

(73) Assignee: TOYOTA JIDOSHA KABUSHIKI KAISHA, Toyota-shi (JP)

(21) Appl. No.: 16/838,154

(22) Filed: Apr. 2, 2020

(30) Foreign Application Priority Data
May 15, 2019 (JP) 2019-092446

(51) Int. Cl. H01L 21/3063; C25F 3/12; H01L 21/308

(52) U.S. Cl. CPC H01L 21/30635; H01L 21/308; C25F 3/12

(57) ABSTRACT

An etching device may include a reservoir storing an etchant, a support member configured to support the semiconductor wafer in a state where a first surface of the semiconductor wafer is immersed in the etchant, a light source configured to irradiate the first surface of the semiconductor wafer supported by the support member with light emitted from the light source, an electrode disposed in the reservoir, and a power source configured to apply a current between the electrode and the semiconductor wafer supported by the support member, the current changing between a first current value and a second current value larger than the first current value.

### CROSS-REFERENCE TO RELATED APPLICATION

This application claims priority to Japanese Patent Application No. 2019-092446, filed on May 15, 2019, the entire contents of which are incorporated herein by reference.

### TECHNICAL FIELD

The technology disclosed herein relates to an etching device. The technology disclosed herein particularly relates to an etching device configured to photoelectrochemically etch a semiconductor wafer.

### BACKGROUND

Japanese Patent Application Publication 2017-212262 describes an etching device configured to etch a semiconductor wafer by photoelectrochemical etching. This etching device includes a reservoir that stores an etchant, a stage on which the semiconductor wafer is placed in a state where the semiconductor wafer is immersed in the etchant, a light source configured to irradiate a surface of the semiconductor wafer placed on the stage with light emitted from the light source, an electrode disposed in the reservoir, and a power source configured to apply a current between the electrode and the semiconductor wafer placed on the stage.

When the semiconductor wafer is to be etched, the semiconductor wafer is irradiated with the light in a state where the current is applied between the semiconductor wafer and the electrode. By doing so, electrons in a valence band of the semiconductor wafer are excited and move beyond a band gap to a conduction band. The excited electrons move from the semiconductor wafer toward the electrode through the power source. Due to the movement of the electrons, holes are generated in a part of the surface of the semiconductor wafer that was irradiated with the light. The surface of the semiconductor wafer is oxidized by these generated holes reacting with the etchant. Then, the oxidized portion of the semiconductor wafer dissolves in the etchant. As above, the semiconductor wafer can be etched by a part of the semiconductor wafer that was irradiated with the light being repeatedly oxidized and dissolved.

### SUMMARY

The etching device of Japanese Patent Application Publication 2017-212262 can etch the surface of the semiconductor wafer, however, it has difficulty in controlling surface roughness of the etched semiconductor wafer. The disclosure herein provides a technology that enables to control post-etching surface roughness of a semiconductor wafer.

An etching device disclosed herein may be configured to etch a semiconductor wafer by photoelectrochemical etching. The etching device may comprise a reservoir storing an etchant, a support member configured to support the semiconductor wafer in a state where a first surface of the semiconductor wafer is immersed in the etchant, a light source configured to irradiate the first surface of the semiconductor wafer supported by the support member with light emitted from the light source, an electrode disposed in the reservoir, and a power source configured to apply a current between the electrode and the semiconductor wafer supported by the support member, the current changing between a first current value and a second current value larger than the first current value.

In the above etching device, the power source applies the current between the semiconductor wafer and the electrode while changing the current value between the first and second current values. By changing the current value as such, post-etching surface roughness changes as compared to a case where the current value is constant. The post-etching surface roughness can be increased or decreased depending on a waveform of the current value. Thus, in the etching device as above, the post-etching surface roughness of the semiconductor wafer can be controlled.

### BRIEF DESCRIPTION OF DRAWINGS

FIG. 1 is a schematic diagram of an etching device 10 of a first embodiment.

FIG. 2 is a diagram showing a waveform of a current which a power source 22 applies to a semiconductor wafer 12 in the first embodiment.

FIG. 3 is a cross-sectional view in a vicinity of a first surface 12a of the semiconductor wafer 12 etched by the etching device 10 of the first embodiment.

FIG. 4 is a diagram showing a waveform of a current which the power source 22 applies to the semiconductor wafer 12 in a second embodiment.

FIG. 5 is a cross-sectional view in the vicinity of the first surface 12a of the semiconductor wafer 12 etched by an etching device of the second embodiment.

FIG. 6 is a diagram showing a waveform of a current which the power source 22 applies to the semiconductor wafer 12 in a third embodiment.

FIG. 7 is a cross-sectional view in the vicinity of the first surface 12a of the semiconductor wafer 12 etched by an etching device of the third embodiment.

FIG. 8 is a diagram showing a waveform of a current which a power source of the comparative example applies to the semiconductor wafer 12.

FIG. 9 is a cross-sectional view in the vicinity of the first surface 12a of the semiconductor wafer 12 etched by an etching device of a comparative example.

### DETAILED DESCRIPTION

Representative, non-limiting examples of the present disclosure will now be described in further detail with reference to the attached drawings. This detailed description is merely intended to teach a person of skill in the art further details for practicing preferred aspects of the present teachings and is not intended to limit the scope of the disclosure. Furthermore, each of the additional features and teachings disclosed below may be utilized separately or in conjunction with other features and teachings to provide improved etching devices, as well as methods for using and manufacturing the same.

Moreover, combinations of features and steps disclosed in the following detailed description may not be necessary to practice the disclosure in the broadest sense, and are instead taught merely to particularly describe representative examples of the disclosure. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### First Embodiment

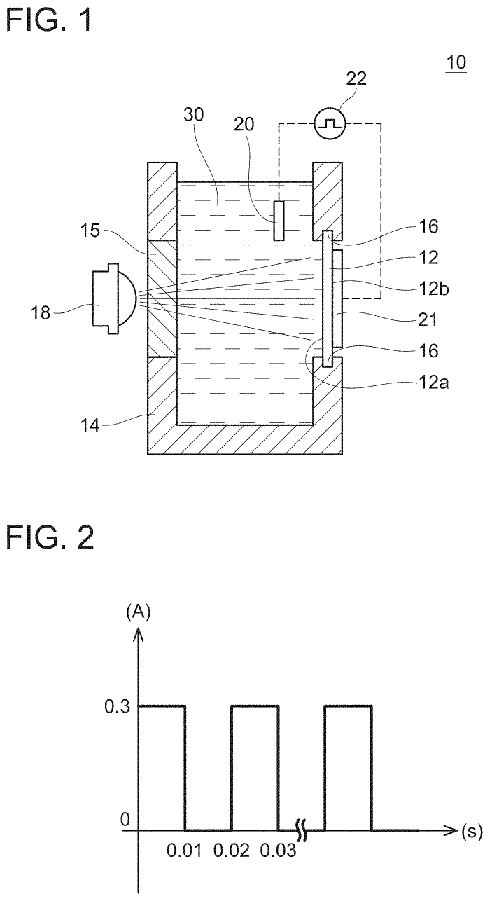

An etching device 10 of a first embodiment will be described with reference to the drawings. The etching device 10 of the present embodiment is an etching device used in photoelectrochemical etching. As shown in FIG. 1, the etching device 10 is provided with a reservoir 14, a support member 16, a light source 18, a first electrode 20, a second electrode 21, and a power source 22. The reservoir 14 stores an etchant 30. The etchant 30 may for example be a mixed aqueous solution of hydrofluoric acid, nitric acid, and surfactant. The mixed aqueous solution may further contain a solvent such as alcohol, for example.

The support member 16 is a tool configured to support a semiconductor wafer 12. The semiconductor wafer 12 has a circular disk shape, and includes a first surface 12a and a second surface 12b. In the present embodiment, the semiconductor wafer 12 is constituted of silicon carbide (SiC). However, the material of the semiconductor wafer 12 is not limited to this, and may for example be another semiconductor material such as silicon (Si). In the etching device 10 of the present embodiment, the support member 16 is provided on one side surface of the reservoir 14. The support member 16 supports the semiconductor wafer 12 by holding a periphery of the semiconductor wafer 12. The support member 16 supports the semiconductor wafer 12 in a state where the first surface 12a of the semiconductor wafer 12 is immersed in the etchant 30. The etching device 10 is configured to photoelectrochemically etch the first surface 12a of the semiconductor wafer 12. In the present embodiment, the first surface 12a of the semiconductor wafer 12 is a C-plane and the second surface 12b of the semiconductor wafer 12 is a Si-plane.

The light source 18 is provided laterally aside the reservoir 14. Further, a sapphire glass 15 is provided on a side surface of the reservoir 14 facing the support member 16. The light source 18 irradiates the first surface 12a of the semiconductor wafer 12 supported by the support member 16 with light emitted therefrom through the sapphire glass 15. A type of the light source 18 is not particularly limited, and a light source which emits ultraviolet light may be used, for example.

The first electrode 20 is disposed within the reservoir 14. The first electrode 20 is immersed in the etchant 30. The first electrode 20 is provided at a position that is displaced from a range connecting the light source 18 and the semiconductor wafer 12 supported by the support member 16. That is, the first surface 12a of the semiconductor wafer 12 supported by the support member 16 is irradiated with the light from the light source 18 without being obstructed by the first electrode 20. The first electrode 20 is constituted of a material that has excellent conductivity and is highly resistant to being dissolved in the etchant 30. The first electrode 20 may for example be constituted of a metallic material such as gold or platinum.

The second electrode 21 is electrically connected with the semiconductor wafer 12 by coming into contact with the second surface 12b of the semiconductor wafer 12 supported by the support member 16.

The power source 22 is connected between the first electrode 20 and the second electrode 21. The power source 22 is configured to apply a current between the first electrode 20 and the second electrode 21. As shown in FIG. 1, one terminal of the power source 22 is connected to the second electrode 21 and the other terminal of the power source 22 is connected to the first electrode 20. As aforementioned, the second electrode 21 is electrically connected with the semiconductor wafer 12 supported by the support member 16. As such, when the power source 22 applies the current between the first electrode 20 and the second electrode 21, the current flows between the first electrode 20 and the semiconductor wafer 12 supported by the support member 16. Although details will be described later, the power source 22 in the present embodiment is configured to be capable of applying a pulse current, which changes periodically between two current values, between the semiconductor wafer 12 and the first electrode 20. Further, the power source 22 is also configured to be capable of applying a direct current. The current values which the power source 22 applies can be controlled for example by using a galvanostat circuit.

Next, the photoelectrochemical etching to the semiconductor wafer 12 using the etching device 10 will be described. Firstly, the semiconductor wafer 12 is set in the etching device 10. That is, the support member 16 is set to support the semiconductor wafer 12, which is a target to be processed, and the second electrode 21 is brought into contact with the second surface 12b of the semiconductor wafer 12. Then, the etchant 30 is stored in the reservoir 14. By doing so, the first surface 12a of the semiconductor wafer 12 comes into contact with the etchant 30. Then, the first electrode 20 is disposed within the etchant 30. After this, the light source 18 is disposed such that the light source 18 faces the first surface 12a of the semiconductor wafer 12.

Next, the power source 22 is turned on to apply the current between the semiconductor wafer 12 and the first electrode 20, and the light source 18 is actuated to irradiate the first surface 12a of the semiconductor wafer 12 with the light. In the present embodiment, as shown in FIG. 2, the power source 22 is controlled to apply the pulse current that changes periodically between 0 A and 0.3 A between the semiconductor wafer 12 and the first electrode 20. As such, a period during which the current flows in the semiconductor wafer 12 and a period during which the current does not flow in the semiconductor wafer 12 appear alternately. The current that flows per unit area of the semiconductor wafer 12 when the power source 22 applies the current of 0.3 A is 780 mA/cm². Further, in the present embodiment, a cycle of the pulse current which the power source 22 applies between the semiconductor wafer 12 and the first electrode 20 is 0.02 s and a duty cycle thereof is 0.5.

When the first surface 12a of the semiconductor wafer 12 is irradiated with the light, electrons in a vicinity of the first surface 12a inside the semiconductor wafer 12 are excited. When this happens, the excited electrons flow to the first electrode 20 through a wiring and the power source 22 by an influence of the current that flows between the semiconductor wafer 12 and the first electrode 20. Due to this, holes are generated in the vicinity of the first surface 12a inside the semiconductor wafer 12. After this, the holes react with the etchant 30, and the holes are diffused into the etchant 30 from the semiconductor wafer 12. The holes diffused into the etchant 30 move through the etchant 30 to the first electrode 20 and bond with the electrons. When the holes react with the etchant 30, an oxidized film (SiO₂) is formed on the first surface 12a of the semiconductor wafer 12. Then, the formed oxidized film dissolves in the etchant 30. The first surface 12a of the semiconductor wafer 12 is etched as above. In the present embodiment, the etching to the semiconductor wafer 12 is completed when the light source 18 has irradiated the first surface 12a with the light and the power source 22 has applied the aforementioned pulse current for 120 seconds, although not particularly limited so.

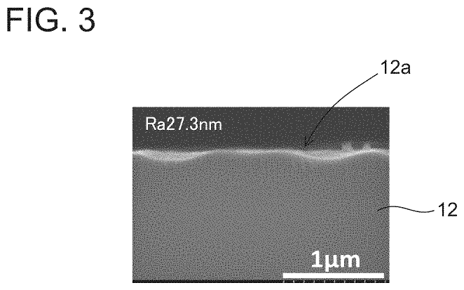

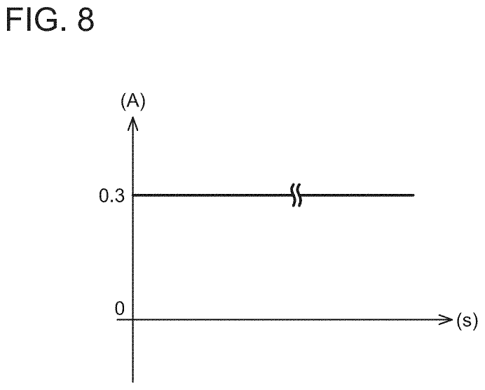

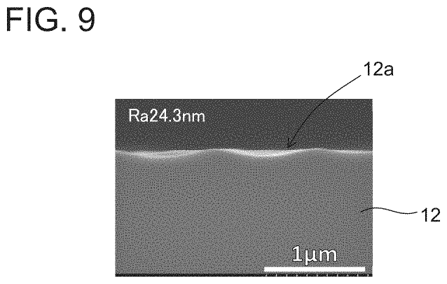

FIG. 3 is a cross-sectional view in the vicinity of the first surface 12a after the semiconductor wafer 12 has been etched under the aforementioned condition. Further, FIG. 9 shows, as a comparative example, a cross-sectional view in the vicinity of the first surface 12a after the semiconductor wafer 12 has been etched using an etching device which differs from the etching device 10 only in the current applied to the semiconductor wafer 12. More specifically, as shown in FIG. 8, in the comparative example, etching was executed by using a power source that applies a constant current (0.3 A) to the semiconductor wafer 12. When the pulse current shown in FIG. 2 was applied, a post-etching surface roughness Ra of the semiconductor wafer 12 was 27.3 nm, whereas when the direct current as shown in FIG. 8 was applied, a post-etching surface roughness Ra of the semiconductor wafer 12 was 24.3 nm. As above, as a result of varying the waveform of the current applied between the semiconductor wafer 12 and the first electrode 20, the post-etching surface roughness (Ra) of the first surface 12a of the semiconductor wafer 12 changed. This is assumed to be due to a mechanism described below.

In the photoelectrochemical etching of the semiconductor wafer 12, the holes are generated inside the semiconductor wafer 12 by the light emitted from the light source 18 and the current that flows in the semiconductor wafer 12. When this happens, the semiconductor wafer 12 is oxidized in its region where the holes are generated. Further, the semiconductor wafer 12 is oxidized also when the generated holes react with the etchant 30. By the semiconductor wafer 12 having undergone these two oxidization processes, the oxidized film is formed on the first surface 12a of the semiconductor wafer 12. It has been found, as a result of study by the inventors, that the oxidization caused by hole generation progresses in a striated pattern along a thickness direction of the semiconductor wafer 12 and the oxidization caused by reaction of the holes and the etchant 30 progresses in a direction along the first surface 12a of the semiconductor wafer 12 (hereinbelow termed a plane direction) in the striated oxidized region. Further, it is assumed that when the oxidized film has been formed over substantially an entirety of the first surface 12a of the semiconductor wafer 12 by the oxidization reaction progressing in the plane direction, the oxidized film exfoliates by dissolving effect of the etchant 30, by which the first surface 12a of the semiconductor wafer 12 is etched. In the etching device 10 of the present embodiment, since the power source 22 applies the pulse current, the hole generation intermittently progresses within the semiconductor wafer 12. By changing the current value applied to the semiconductor wafer 12 to control a rate of the oxidization of the semiconductor wafer 12 caused by the hole generation, the post-etching surface roughness of the semiconductor wafer 12 can be controlled.

### Second Embodiment

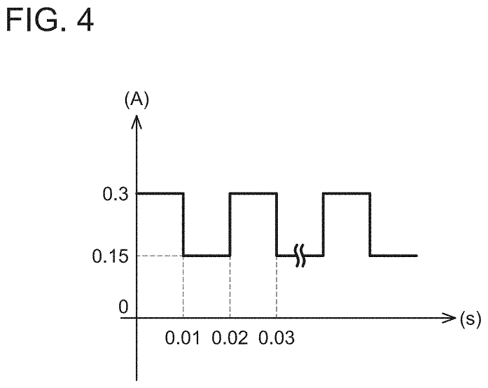

In an etching device of a second embodiment, a waveform of a current which the power source 22 applies differs from that of the first embodiment. Other configurations are the same as those of the first embodiment. In the second embodiment, as shown in FIG. 4, the power source 22 is controlled to apply the current that changes periodically between 0.15 A and 0.3 A between the semiconductor wafer 12 and the first electrode 20. That is, in the present embodiment, the current constantly flows in the semiconductor wafer 12 during etching, however, the current value flowing in the semiconductor wafer 12 changes repeatedly. In the present embodiment, a cycle of the current which the power source 22 applies between the semiconductor wafer 12 and the first electrode 20 is 0.02 s.

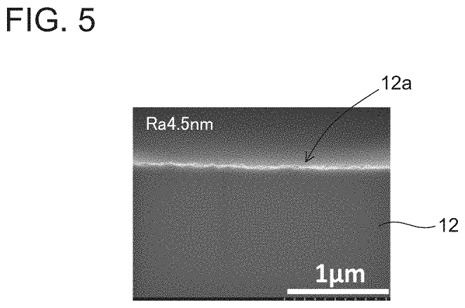

FIG. 5 is a cross-sectional view in the vicinity of the first surface 12a after the semiconductor wafer 12 has been etched under the aforementioned condition. As shown in FIG. 5, a post-etching surface roughness Ra of the semiconductor device 12 became 4.5 nm under the condition of the second embodiment. As can be understood from FIG. 5, by controlling the current value applied to the semiconductor wafer 12 such that it changes repeatedly between the values that are larger than zero, the post-etching surface roughness of the first surface 12a of the semiconductor wafer 12 was significantly decreased as compared to the case where the current value is constant (see the comparative example of FIG. 8). The semiconductor wafer 12 etched by using the etching device of the present embodiment has very low surface roughness. Due to this, for example, it can suitably be used for epitaxially grow a semiconductor material such as SiC on an etched surface.

### Third Embodiment

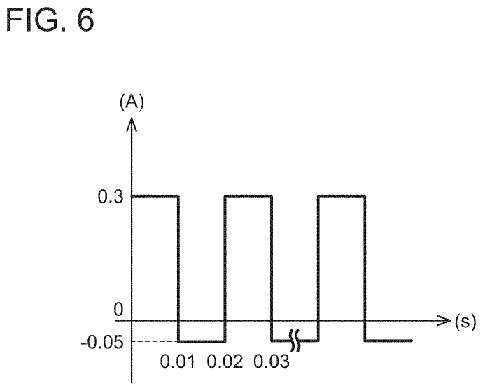

In an etching device of a third embodiment, a waveform of a current which the power source 22 applies differs from that of the first embodiment. Other configurations are the same as those of the first embodiment. In the third embodiment, as shown in FIG. 6, the power source 22 is controlled to apply a current that changes periodically between −0.05 A and 0.3 A between the semiconductor wafer 12 and the first electrode 20. That is, in the present embodiment, a polarity of the current that flows in the semiconductor wafer 12 repeatedly changes during etching. In the present embodiment, a cycle of the current which the power source 22 applies between the semiconductor wafer 12 and the first electrode 20 is 0.02 s.

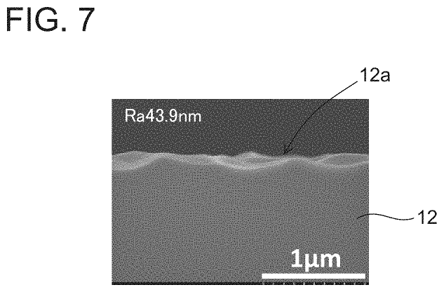

FIG. 7 is a cross-sectional view in the vicinity of the first surface 12a after the semiconductor wafer 12 has been etched under the aforementioned condition. As shown in FIG. 7, a post-etching surface roughness Ra of the semiconductor device 12 became 43.9 nm under the condition of the third embodiment. As can be understood from FIG. 7, by controlling the current value applied to the semiconductor wafer 12 such that it changes repeatedly between the value larger than zero and the value smaller than zero, the post-etching surface roughness of the first surface 12a of the semiconductor wafer 12 was significantly increased as compared to the case where the current value is constant (see the comparative example of FIG. 8). The semiconductor wafer 12 etched by using the etching device of the present embodiment has very high surface roughness, and thus its property to have a metal film adhered to the etched surface is high. Due to this, the etched semiconductor wafer 12 can, for example, be used suitably for forming a metal film on the etched surface.

In the aforementioned embodiments, the power source 22 is configured to apply the current that changes periodically between two current values. However, the power source 22 simply needs to be configured to apply the current that changes between two current values. That is, the current which the power source 22 applies does not need to change periodically.

A relationship between the constituent features of the aforementioned embodiments and the constituent features of the claims will be described. The first electrode 20 in the embodiments is an example of an electrode in the claims.

Some of the features characteristic to the technology disclosed herein will be listed below. It should be noted that the respective technical elements are independent of one another, and are useful solely or in combinations.

In a configuration disclosed herein as an example, the current may change periodically between the first current value and the second current value.

In a configuration disclosed herein as an example, the current may be a pulse current.

In a configuration disclosed herein as an example, the first current value may be larger than zero.

In such a configuration, the post-etching surface roughness of the semiconductor wafer can be decreased.

In a configuration disclosed herein as an example, the second current value may be larger than zero and the first current value may be smaller than zero.

In such a configuration, the post-etching surface roughness of the semiconductor wafer can be increased.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present disclosure is not limited to the combinations described at the time the claims are filed. Further, the purpose of the examples illustrated by the present description or drawings is to satisfy multiple objectives simultaneously, and satisfying any one of those objectives gives technical utility to the present disclosure.

What is claimed is:

1. An etching device configured to etch a semiconductor wafer by photoelectrochemical etching, the etching device comprising:
a reservoir storing an etchant;
a support member configured to support the semiconductor wafer in a state where a first surface of the semiconductor wafer is immersed in the etchant;
a light source configured to irradiate the first surface of the semiconductor wafer supported by the support member with light emitted from the light source;
an electrode disposed in the reservoir; and
a power source configured to apply a current between the electrode and the semiconductor wafer supported by the support member, the current changing between a first current value and a second current value larger than the first current value.

2. The etching device of claim 1, wherein
the current changes periodically between the first current value and the second current value.

3. The etching device of claim 2, wherein
the current is a pulse current.

4. The etching device of claim 2, wherein
the first current value is larger than zero.

5. The etching device of claim 2, wherein
the second current value is larger than zero and the first current value is smaller than zero.

6. The etching device of claim 1, wherein
the semiconductor wafer is constituted of silicon carbide.

7. The etching device of claim 6, wherein
the first surface of the semiconductor wafer is a C-plane.
